(19) United States
(12) Patent Application Publication
(10) Pub. No.: US 2008/0014736 A1
(43) Pub. Date: Jan. 17, 2008

(54) Semiconductor device and manufacturing process therefor

(75) Inventor: Keizo Kawakita, Tokyo (JP)

Correspondence Address: YOUNG & THOMPSON, 745 SOUTH 23RD STREET, 2ND FLOOR, ARLINGTON, VA, 22202, US

(73) Assignee: ELPIDA MEMORY, INC., TOKYO (JP)

(21) Appl. No.: 11/822,338

(22) Filed: Jul. 5, 2007

(30) Foreign Application Priority Data
Jul. 5, 2006 (JP) 2006-185299

(51) Int. Cl. H01L 21/44

(52) U.S. Cl. 438/597

(57) ABSTRACT

A semiconductor device including a polysilicon plug with a reduced contact resistance and a manufacturing process therefor. The process includes the steps of forming a hole in an insulating layer on a semiconductor substrate; forming polysilicon over the whole surface of the insulating layer such that it fills the hole; forming a polysilicon plug in the hole by etching back a polysilicon; and heating the semiconductor substrate including the polysilicon plug within the insulating layer under a hydrogen atmosphere.

This application is based upon and claims the benefit of priority from Japanese patent application No. 2006-185299, filed on Jul. 5, 2006, the disclosure of which is incorporated herein in its entirety by reference.

### BACKGROUND OF THE INVENTION

1. Field of the Invention

The present invention relates to a semiconductor device and a manufacturing process therefor, particularly to a semiconductor device including a polysilicon plug and a manufacturing process therefor.

2. Description of the Related Art

In semiconductor devices such as DRAM (Dynamic Random Access Memory), elements have been miniaturized in response to increasing demand for size-reduction and improved performance in products. In a semiconductor device, interlayer electric connection is sometimes made by burying polysilicon as a plug in a hole formed in an insulating layer. Such polysilicon can be deposited by, for example, CVD. Recently, for miniaturizing an element with a polysilicon plug, there have been required for reducing a resistance of the polysilicon plug and minimizing variation in a resistance.

In response to the above requirements, Japanese Laid-open Patent Publication No. 2005-277327 has disclosed a technique for a process for manufacturing a semiconductor device having a low-resistance plug. More specifically, Japanese Laid-open Patent Publication 2005-277327 has described a process for manufacturing a semiconductor device comprising the steps of depositing a barrier metal on a polysilicon plug via a contact metal and heating the barrier metal by heating a substrate at 500° C. or higher under nitrizing-gas atmosphere.

Japanese Laid-open Patent Publication 2005-332960 has disclosed, as Japanese Laid-open Patent Publication 2005-277327, a process for manufacturing a contact plug with a lower resistance. More specifically, Japanese Laid-open Patent Publication 2005-332960 has described a process for manufacturing a semiconductor device comprising the steps of forming a silicon crystal core on a substrate; depositing the first amorphous silicon; depositing a second amorphous silicon; and growing the crystal core in solid phase to crystallize the first amorphous silicon and the second amorphous silicon.

When polysilicon is deposited as a plug over the whole surface including a hole, there may be formed a fine concave on the upper surface of the polysilicon formed over the hole along the shape of the hole. It is due to coverage during the polysilicon deposition. Furthermore, the concave may extend during etching back the polysilicon, leading to a larger step. That is, in this case, a fine trench is formed over the plug.

When a contact structure such as a metal plug is piled on a polysilicon plug, it is necessary to homogeneously form a metal silicide for reducing a contact resistance in the interface. However, a fine trench formed in the interface between the polysilicon plug and the metal plug as described above may make it difficult to homogeneously form a metal silicide, leading to increase in a contact resistance. It also causes increase in variation of a contact resistance. Such increase in a contact resistance and in variation of a contact resistance may lead to interference with normal operations of a semiconductor device.

In view of the above problems, an exemplary object of the present invention is to provide a semiconductor device including a polysilicon plug with a reduced contact resistance and a manufacturing process therefor. Another exemplary object of the present invention is to provide a semiconductor device including a polysilicon plug in which variation of a contact resistance is minimized and a manufacturing process therefor.

### SUMMARY OF THE INVENTION

Means for achieving the above object will be expressed as follows. Technical matters in the following expression are followed by, for example, numbers or symbols in parentheses ( ). These numbers and symbols are identical to reference numbers and symbols in technical matters constituting at least one of multiple embodiments or examples of the present invention, particularly in technical matters expressed in a drawing corresponding to the embodiment or example. Such reference numbers and reference symbols define correspondence between and link between the technical matters described in the claims and the technical matters in the embodiments or the examples. It is not to be understood that such correspondence and linkage limit the technical matters described in the claims to the technical matters in the embodiments or the examples.

An exemplary aspect of the present invention is a process for manufacturing a semiconductor device comprising the steps of forming a hole (1) within an insulating layer (2) on a semiconductor substrate (3) (Step S1); forming a polysilicon (4a) over the whole surface of the insulating layer such that the polysilicon (4a) fills the hole (1) (Step S2); forming a polysilicon plug (4) in a hole by etching back the polysilicon (Step S3); and conducting hydrogen annealing by heating the semiconductor substrate (3) comprising the polysilicon plug within the insulating layer under a hydrogen atmosphere (Step S5).

In the above process for manufacturing a semiconductor device, from one aspect, the step of forming a polysilicon plug (S3) is preferably the step of forming a polysilicon plug by etching back the polysilicon (4a) until the height of the opening in the hole (1) become equal to that of the upper surface of the polysilicon plug (4) (Step S3-1).

In the above process for manufacturing a semiconductor device, from another aspect, the step of forming a polysilicon plug (S3) is preferably the step of forming a polysilicon plug by etching back the insulating layer (2) such that the upper part of the polysilicon plug (4) includes a convex shape protruding upward from the surface of the insulating layer (2) (Step S3-4).

The above process for manufacturing a semiconductor device preferably comprises the step of selective epitaxial growth (Step S3-5) in which silicon is selectively epitaxially grown on a region where the polysilicon plug (4) is exposed between the steps of forming a polysilicon plug and of conducting hydrogen annealing. In such a case, the step of hydrogen annealing (S5) is conducted after the step of selective epitaxial growth (S3-5).

In the above process for manufacturing a semiconductor device, the polysilicon plug (4) is preferably formed as a plug connecting a bit line in a DRAM to an impurity diffusion layer, or a plug connecting a capacitor to an impurity diffusion layer.

In the above process for manufacturing a semiconductor device, the step of conducting hydrogen annealing (S5) is preferably conducted under the conditions of a temperature of the semiconductor substrate comprising the polysilicon plug of 800° C. to 900° C. both inclusive and a duration of 10 sec to 60 sec both inclusive.

An exemplary aspect of the invention is a semiconductor device comprising a semiconductor substrate (3); an insulating layer (2) formed on the semiconductor substrate (3); a hole (1) formed within the insulating layer (2); a polysilicon plug (4) buried in the hole (1), wherein the upper surface of the polysilicon plug (4) is a curved surface.

According to the present invention, there are provided a semiconductor device comprising a polysilicon plug with a reduced contact resistance and a manufacturing process therefor.

According to the present invention, there are also provided a semiconductor device comprising a polysilicon plug in which variation in a contact resistance is minimized and a manufacturing process therefor.

### BRIEF DESCRIPTION OF THE DRAWINGS

FIG. 1 shows a cross section in the course of manufacturing a semiconductor device according to Embodiment 1.

FIG. 2 shows a cross section in the course of manufacturing a semiconductor device according to Embodiment 1.

FIG. 3A shows a cross section in the course of manufacturing a semiconductor device according to Embodiment 1.

FIG. 3B shows a cross section in the course of manufacturing a semiconductor device according to Embodiment 1.

FIG. 4A shows a cross section in the course of manufacturing a semiconductor device according to Embodiment 1.

FIG. 4B shows a cross section in the course of manufacturing a semiconductor device according to Embodiment 1.

FIG. 5 shows a cross section in the course of manufacturing a semiconductor device according to Embodiment 1.

FIG. 6 shows a cross section in the course of manufacturing a semiconductor device according to Embodiment 1.

FIG. 7 shows a cross section in the course of manufacturing a semiconductor device according to Embodiment 1.

FIG. 8 shows a cross section in the course of manufacturing a semiconductor device according to Embodiment 1.

FIG. 9 shows a cross section in the course of manufacturing a semiconductor device according to Embodiment 1.

FIG. 10A shows a cross section in the course of manufacturing a semiconductor device according to Embodiment 2.

FIG. 10B shows a cross section in the course of manufacturing a semiconductor device according to Embodiment 2.

FIG. 11A shows a cross section in the course of manufacturing a semiconductor device according to Embodiment 2.

FIG. 11B shows a cross section in the course of manufacturing a semiconductor device according to Embodiment 2.

FIG. 12 shows a cross section in the course of manufacturing a semiconductor device according to Embodiment 2.

FIG. 13 shows a cross section in the course of manufacturing a semiconductor device according to Embodiment 2.

FIG. 14A shows a cross section in the course of manufacturing a semiconductor device according to Embodiment 3.

FIG. 14B shows a cross section in the course of manufacturing a semiconductor device according to Embodiment 3.

FIG. 15A shows a cross section in the course of manufacturing a semiconductor device according to Embodiment 3.

FIG. 15B shows a cross section in the course of manufacturing a semiconductor device according to Embodiment 3.

FIG. 16 shows a cross section in the course of manufacturing a semiconductor device according to Embodiment 4.

FIG. 17 shows a cross section in the course of manufacturing a semiconductor device according to Embodiment 4.

FIG. 18 shows a cross section in the course of manufacturing a semiconductor device according to Embodiment 4.

FIG. 19 is a plan view showing a pattern layout of a semiconductor device according to the present invention.

FIG. 20 is a plan view showing a pattern layout of a semiconductor device according to the present invention.

FIG. 21 shows a flow chart of a manufacturing process for a semiconductor device according to Embodiment 1.

FIG. 22 shows a flow chart of a manufacturing process for a semiconductor device according to Embodiment 2.

FIG. 23 shows a flow chart of a manufacturing process for a semiconductor device according to Embodiment 3.

FIG. 24 shows a flow chart of a manufacturing process for a semiconductor device according to Embodiment 4.

### DETAILED DESCRIPTION OF PREFERRED EMBODIMENTS

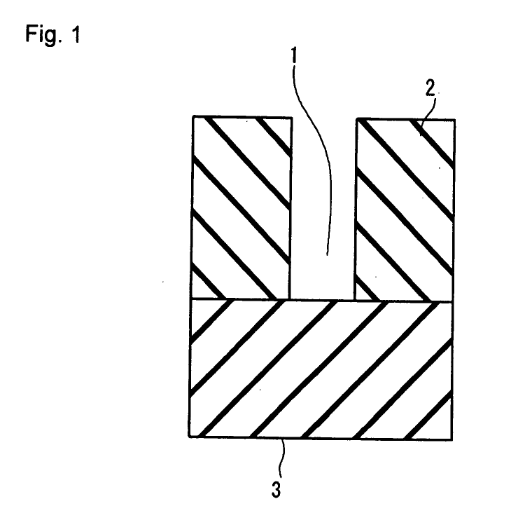

In the FIGS. 1-24, symbols 1 and 8 show contact hole and symbols 2, 7 and 25 show silicon oxide film. Symbol 21 shows cover film and symbol 22 shows sidewall. Symbols 23, 24, 73 and 75 show interlayer insulating films and symbol 3 shows silicon substrate. Symbol 4 shows polysilicon plug and symbols 4a and 18 show polysilicon. Symbol 5 shows trench and symbol 6 shows gate electrode. Symbol 61 shows gate polysilicon and symbol 62 shows gate tungsten. Symbol 9 shows Ti, TiN laminate film and symbol 10 shows titanium silicide layer. Symbol 11 shows tungsten plug and symbol 12 and 13 show selective epitaxial silicon. Symbol 27 shows bit line and symbol 31 shows gate insulating film. Symbol 70 shows diffusion layer and symbol 71 shows bit line contact plug. Symbol 72 shows silicon nitride film and symbol 74 shows capacity contact plug. Symbol 76 shows lower electrode and symbol 77 shows capacity insulating film. Symbol 78 shows upper electrode and symbol 90 shows element separating region. Symbol 100 shows semiconductor device and symbol 101 shows active region. Symbol 102 shows word line.

### Embodiment 1

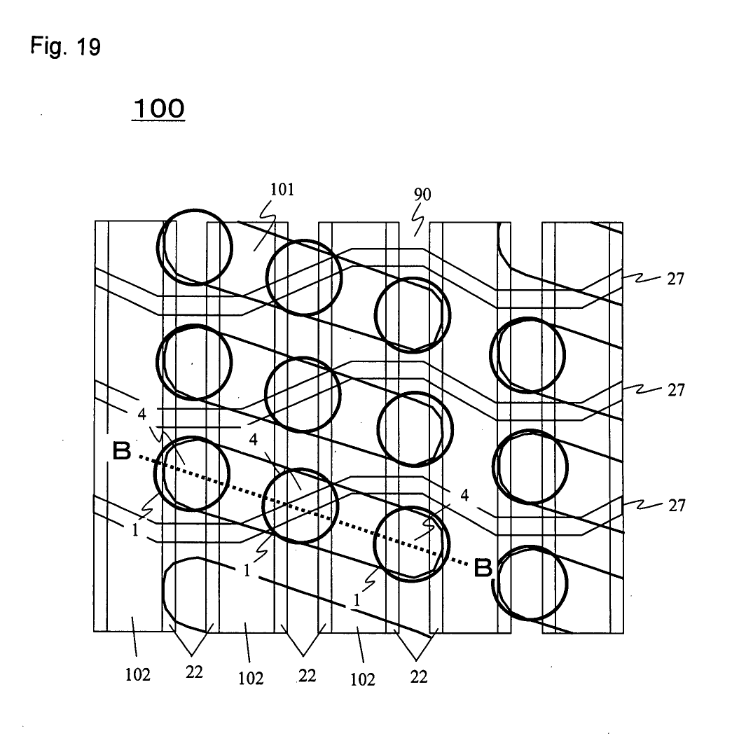

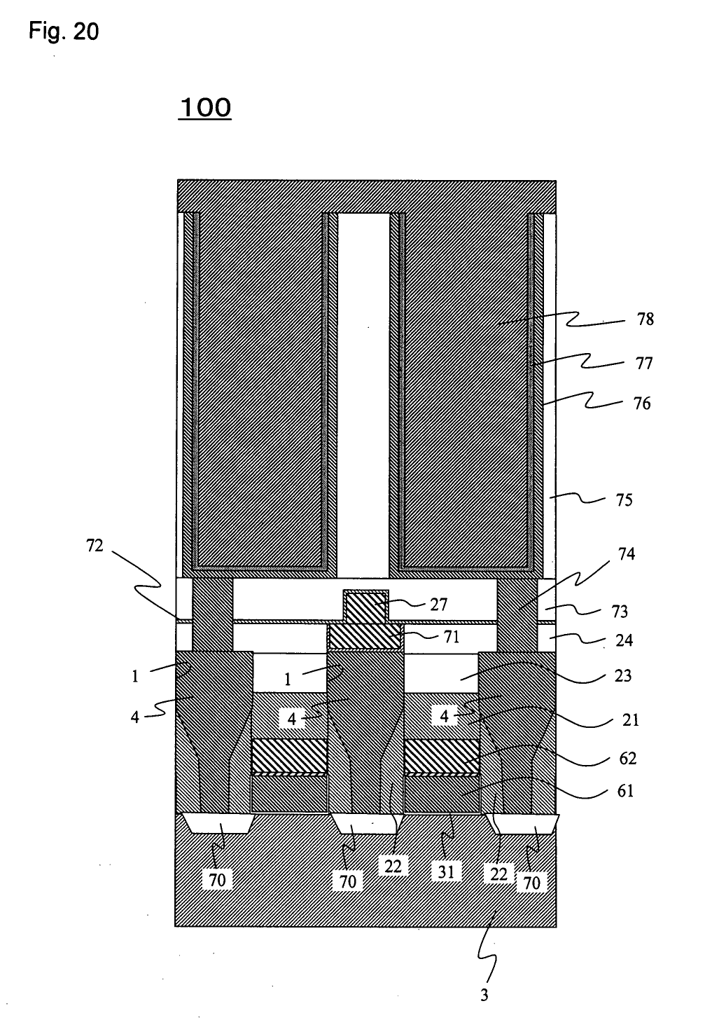

There will be described Embodiment 1 where the present invention is applied to a semiconductor device 100 comprising a DRAM with reference to the drawings. First, a DRAM memory cell will be outlined with reference to FIGS. 19 and 20. FIG. 19 shows a plan view of a memory cell and FIG. 20 shows a cross-sectional view taken on line B-B in FIG. 19. In these figures, identical components are indicated by the same symbols.

First, see the plan view of FIG. 19. Each component in the layout illustrated in FIG. 19 is formed on a semiconductor substrate 3. For ease of explanation, the structures, which cannot be seen because of interruption by an interlayer insulating film and so on, are made visible by perspective representation. On the semiconductor substrate 3, there are formed a plurality of active regions 101 surrounded by element separating regions 90. There are formed a plurality of word lines (gate electrodes) 102 such that they traverse longitudinally the plurality of active regions 101. Each word line 102 comprises sidewall insulating film 22. A region on the active region 101 sandwiched by the word lines 102 comprises a dopant diffusion layer. A contact hole 1 is formed on the dopant diffusion layer, a contact plug 4 connected to the diffusion layer is formed within the contact hole 1. There are formed a plurality of bit lines 27 such that they are connected to the contact plug 4 on the diffusion layer at the center of the active region 101 and are perpendicular to the word lines 102.

Next, see the cross-sectional view of FIG. 20. On the semiconductor substrate 3 in the active region 101 are deposited a gate insulating film 31, polysilicon for a gate electrode (hereinafter, referred to as “gate polysilicon”) 61, tungsten for a gate electrode (hereinafter, referred to as “gate tungsten”) 62 and a cover film 21. The gate polysilicon 61 and the gate tungsten 62 constitute a gate electrode 6. The gate electrode 6 constitutes the word line 102 in FIG. 19.

The sidewall of the gate electrode 6 comprises a sidewall insulating film 22, and a diffusion layer region 70 is formed in the surface of the semiconductor substrate 3. An interlayer insulating film 23 formed over the whole surface comprises the contact hole 1. The contact plug 4 is formed within the contact hole 1 such that the contact plug 4 connects to the diffusion layer 70. A bit line contact plug 71 within the interlayer insulating film 24 is formed on the central contact plug 4 and a bit line 27 is formed on the bit line contact 71.

The bit line 27 is covered by a silicon nitride film 72 and an interlayer insulating film 73. Capacity contact plugs 74 are formed on the contact plugs 4 in both sides and capacity contact plugs 74 are connected to a capacitor comprising a lower electrode 76, a capacity insulating film 77 and an upper electrode 78 formed within an interlayer insulating film 75. Although being not shown, an upper interconnection layer is formed to provide a semiconductor device for a DRAM.

A silicon substrate is used for the semiconductor substrate 3. A silicon nitride film is used for the cover film 21 and the sidewall insulating film 22, and a silicon oxide film is used for the interlayer insulating film 23.

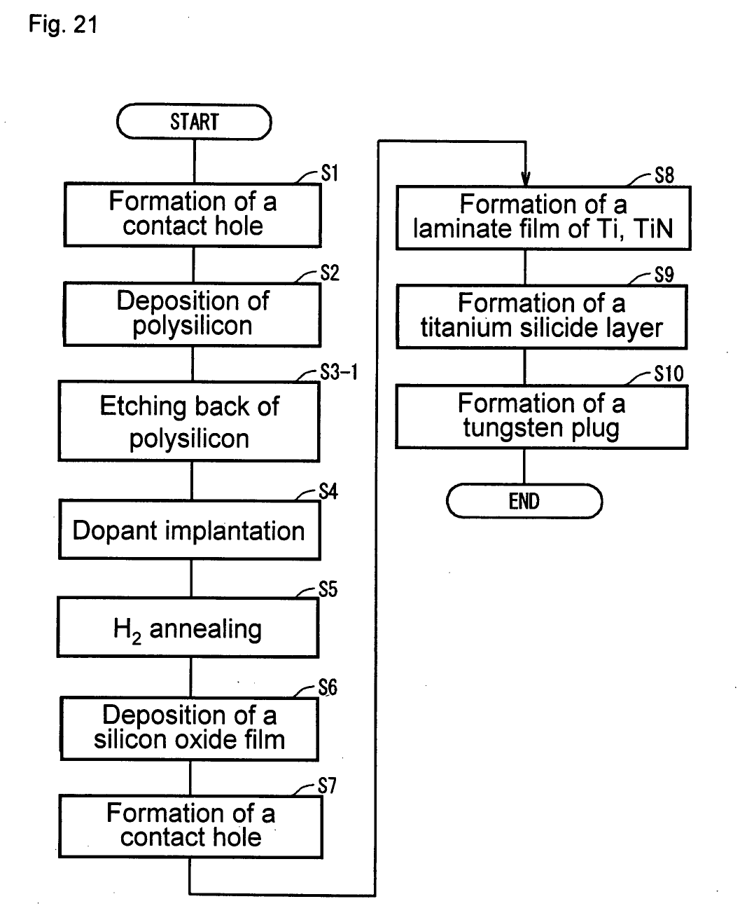

FIG. 21 is a flow chart illustrating a manufacturing process for a semiconductor device 100 according to Embodiment 1, where a contact plug is formed in the above contact hole 1. The processing in Steps S1110 provide a contact plug as shown in FIG. 9. Each step in FIG. 21 will be described in detail with reference to FIGS. 1 to 9.

### Step S1: Forming a Contact Hole

First, see FIG. 1. FIG. 1 is a cross-sectional view schematically illustrating only the contact hole 1 of the central part in the cross-sectional view of FIG. 20. For ease of explanation, gate electrodes (a gate polysilicon 61 and a gate tungsten 62) are not shown. FIG. 1 shows the state where an insulating layer of a silicon oxide film 2 is formed on a semiconductor substrate of a silicon substrate 3 and the contact hole 1 is formed in the silicon oxide film 2. The silicon oxide film 2 is deposited by plasma CVD using tetraethoxysilane (TEOS) as a starting material. The silicon oxide film 2 may be formed using PSG (Phosph Silicate Glass) containing phosphorous or BPSG (Boro-Phosph Silicate Glass) containing boron and phosphorous. The contact hole 1 is formed by lithography and dry etching. In the process, dry etching of the silicon oxide film can be conducted by a fluorine-containing plasma using, for example, octafluorocyclobutane (C₄F₈) as an etching gas. The contact hole has a diameter of 70 nm.

### Step S2: Deposition of Polysilicon

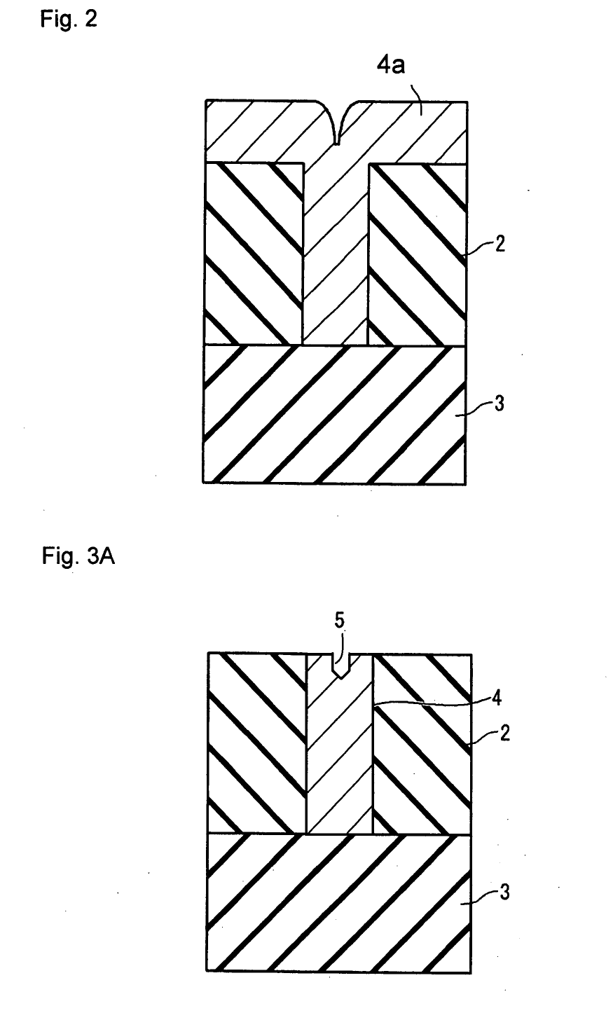

Next, see FIG. 2. A polysilicon 4a is deposited to a thickness of 50 nm such that it fills the contact hole 1. Here, since the contact hole has a diameter of 70 nm, the contact hole can be completely filled with polysilicon with a thickness of 50 nm. The polysilicon 4a is deposited by CVD using monosilane (SiH₄) and phosphine (PH₃) as a source gas. The polysilicon may be formed by first forming amorphous silicon, which is then converted to polysilicon in subsequent annealing. The polysilicon 4a is also deposited over the silicon oxide film 2 other than the contact hole 1. In the region of the contact hole 1, a concave is formed in the surface of the polysilicon 4a due to a coverage difference from the flat part.

### Step S3-1: Etching Back

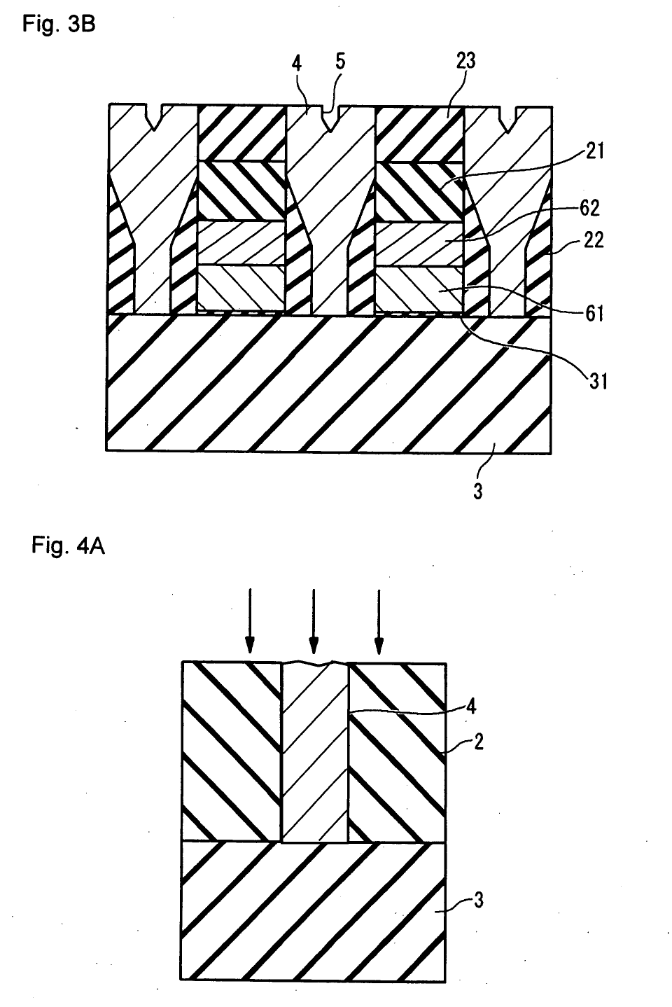

Next, see FIGS. 3A, B. FIG. 3A is a cross-sectional view of the state next to that in FIG. 2 and FIG. 3B is a cross-sectional view of the selected area of interest shown in FIG. 20. In this step, the polysilicon 4a is etched back for removing the polysilicon 4a deposited over the region other than the contact hole 1. The etching back can be conducted by anisotropic dry etching using a chlorine-containing plasma. By the etching back, the polysilicon 4a is buried to the substantially same level as the opening in the upper part of the contact hole 1, to form the polysilicon plug 4. Furthermore, the etching back further extends the concave formed in Step S2, to give a trench 5 with a larger step.

### Step S4: Dopant Implantation

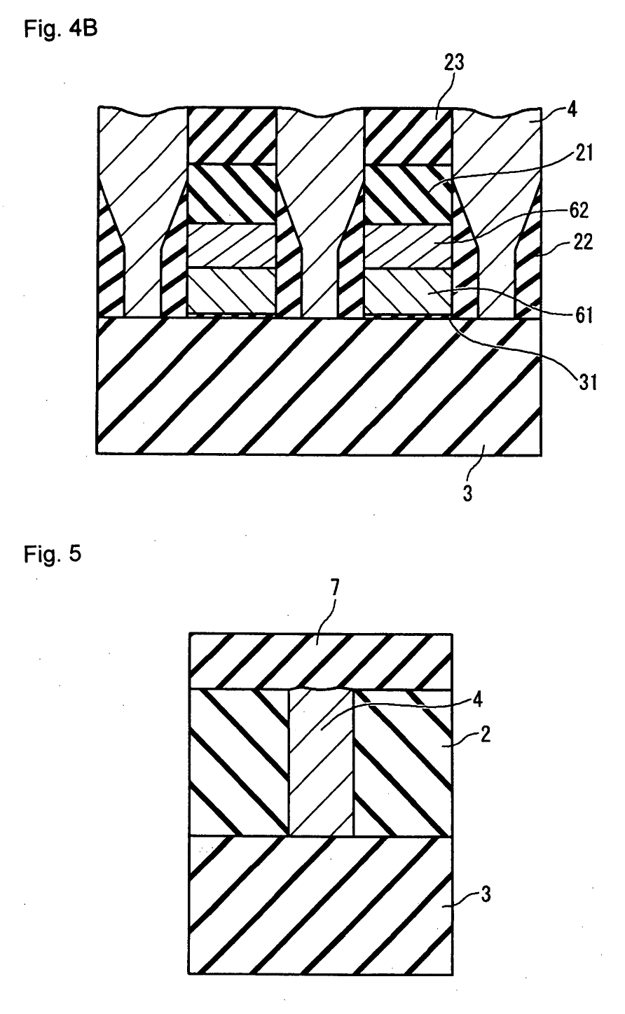

Next, see FIGS. 4A, B. In this step, a dopant is implanted into the polysilicon plug 4 by ion implantation. The dopant implanted may be boron or phosphorous. In the processing in Step S2, the ion implantation can be omitted when the polysilicon 4a which has been implanted by a dopant in advance is deposited.

### Step S5: Hydrogen Annealing

Then, the semiconductor substrate with the polysilicon plug is heated (H₂ annealed) under a hydrogen atmosphere. By the hydrogen annealing, silicon atoms move in the surface of the polysilicon plug 4 such that a surface energy becomes minimum, that is, such that convexoconcave is removed. As a result, the surface of the polysilicon plug 4 becomes a smooth curved surface to eliminate the trench 5.

The hydrogen annealing is preferably conducted under the conditions of a temperature of the semiconductor substrate with the polysilicon plug of 800° C. to 900° C. both inclusive and a duration of 10 sec to 60 sec both inclusive. If the substrate temperature is lower than 800° C. or the duration is shorter than 10 sec, the surface of the polysilicon plug 4 may be inadequately smooth. If the substrate temperature is higher than 900° C. or the duration is longer than 60 sec, the polysilicon plug 4 may be so deteriorated that it cannot adequately act as a plug.

### Step S6: Deposition of a Silicon Oxide Film

Next, see FIG. 5. In this step, an interlayer insulating film of a silicon oxide film 7 with a thickness of 70 nm is deposited over the whole surface. The silicon oxide film 7 is deposited by plasma CVD using TEOS as a starting material.

### Step S7: Formation of a Contact Hole

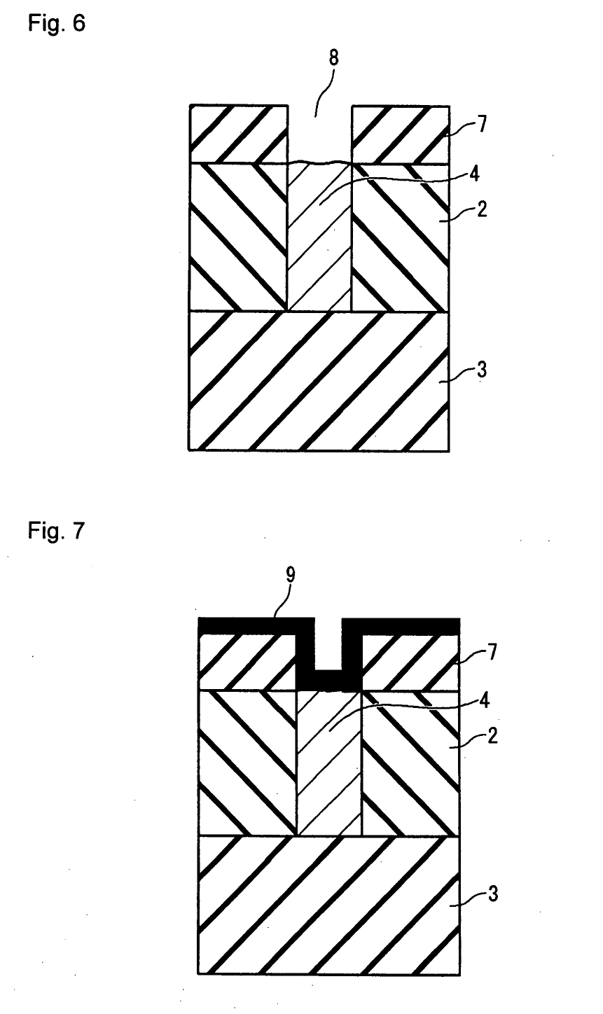

Next, see FIG. 6. In this step, a contact hole 8 for forming a tungsten plug is formed within the silicon oxide film 7 by lithography and anisotropic dry etching. The contact hole 8 is formed at the position just above the contact plug 4. The silicon oxide film is dry-etched by a fluorine-containing plasma using, for example, octafluorocyclobutane (C₄F₈) as an etching gas.

### Step S8: Formation of Ti, TiN Laminate Film

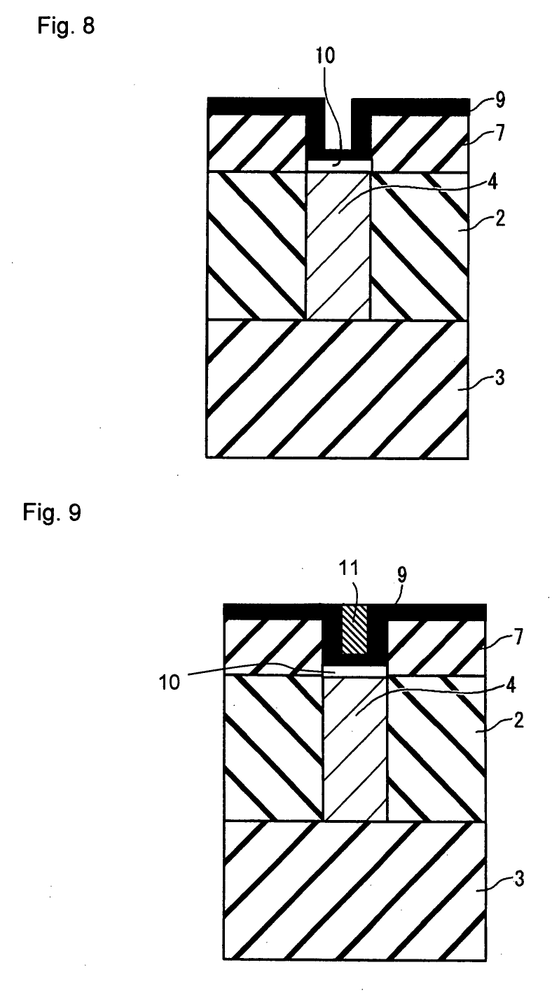

Next, see FIG. 7. In this step, following the contact hole 8, a laminate film 9 comprising Ti with a thickness of 10 nm and TiN with a thickness of 10 nm is sequentially formed by, for example, sputtering. Here, the laminate film 9 of Ti and TiN is deposited on the upper surface of the polysilicon plug 4 which has been smooth after removal of the trench 5. The laminate film 9 of Ti and TiN can be formed by CVD in place of sputtering.

### Step S9: Formation of a Titanium Silicide Layer

Next, see FIG. 8. After forming the laminate film 9 of Ti and TiN, it is annealed under a non-oxidative atmosphere at 650° C. or higher. By the annealing, Ti with a thickness of 10 nm reacts with the polysilicon plug 4 to form a titanium silicide layer 10. When the laminate film 9 of Ti and TiN is formed by CVD, the above annealing can be omitted because the titanium silicide layer 10 is formed during Ti deposition. In this case, the laminate film 9 of the titanium silicide layer 10 and TiN have been already formed immediately after depositing TiN. Furthermore, since a silicon oxide film does not react with Ti, titanium silicide is not formed in the region other than the polysilicon plug. TiN acts as a barrier film for preventing the polysilicon plug from reacting with tungsten deposited later.

### Step S10: Formation of a Tungsten Plug

Next, see FIG. 9. After forming tungsten to a thickness of 100 nm by CVD using tungsten fluoride (WF₆) as a starting material over the whole surface, it is etched back by a plasma containing chlorine gas, to form a tungsten plug 11. The etching back may be conducted by CMP (Chemical Mechanical Polishing).

Steps S1 to 10 described above provide a contact structure comprising a laminate of the polysilicon plug 4 and the tungsten plug 11. The tungsten plug 11 corresponds to the bit line contact plug 71 in FIG. 20 and is subsequently connected to the bit line 27 by a given procedure. As a result, the diffusion layer 70 is connected to the bit line 27 via the polysilicon plug 4 and the bit line contact plug 71. Furthermore, a capacity contact plug 74 can be also formed in a similar configuration, where the diffusion layer 70 can be connected to a capacitor via the polysilicon plug 4 and the capacity contact plug 74.

As described above, according to this embodiment, the trench 5 formed in the upper surface of the polysilicon plug 4 can be deleted by the hydrogen annealing in Step S5 to make the upper surface of the polysilicon plug 4 smooth.

In the related art, when the laminate film 9 of Ti and TiN is formed in the presence of the trench 5 in the upper surface of the polysilicon plug 4, coverage in CVD or sputtering may be insufficient, so that there may generate a region where the laminate film 9 is inadequately deposited. As a result, titanium silicide is not homogeneously formed, leading to increase in a contact resistance or increased variation in a contact resistance.

In contrast, in this embodiment, since the laminate film 9 of Ti and TiN is formed on a smooth polysilicon plug surface, the laminate film 9, particularly Ti can be formed in an even thickness. Consequently, since the titanium silicide layer can be also evenly formed, increase in a contact resistance can be prevented and increase in variation of a contact resistance can be prevented.

### Embodiment 2

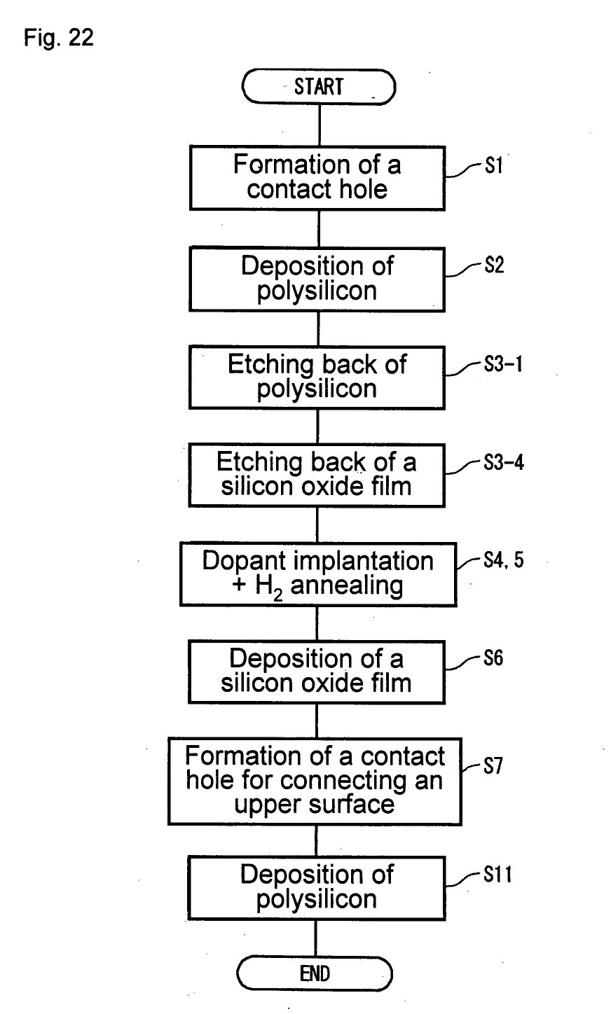

There will be described Embodiment 2. FIG. 22 is a flow chart of a manufacturing process for a semiconductor device according to this embodiment. In this embodiment, the shape of the polysilicon plug 4 during hydrogen annealing is modified in comparison with Embodiment 1. Furthermore, this embodiment will be described for the case of forming another polysilicon plug instead of a tungsten plug on the polysilicon plug 4 as in Embodiment 1.

### Step S1, 2: Formation of a Contact Hole and Deposition of Polysilicon

As described in Embodiment 1, a contact hole 1 is formed (S1) and a polysilicon 4a is deposited (S2).

### Step S3-1: Etching Back of Polysilicon

As described in Embodiment 1, the polysilicon 4a deposited on the region other than the contact hole 1 was removed by etching back to form a polysilicon plug 4.

### Step S3-4: Etching Back of a Silicon Oxide Film

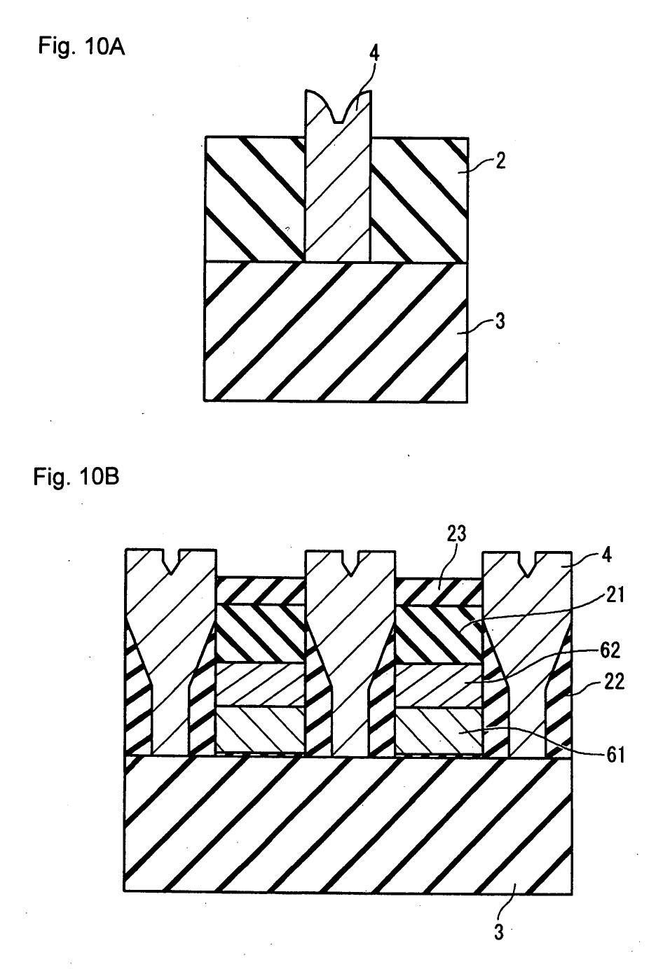

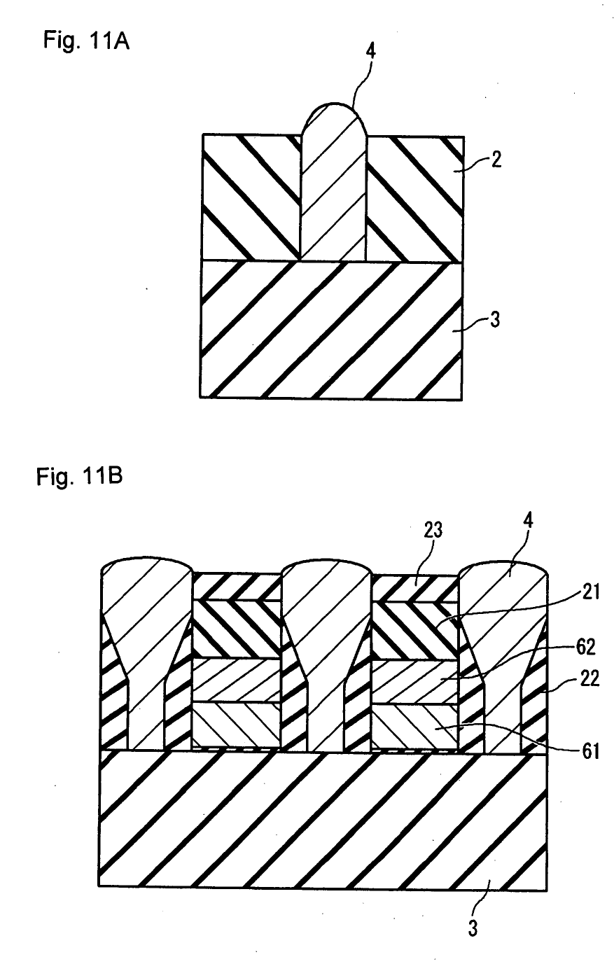

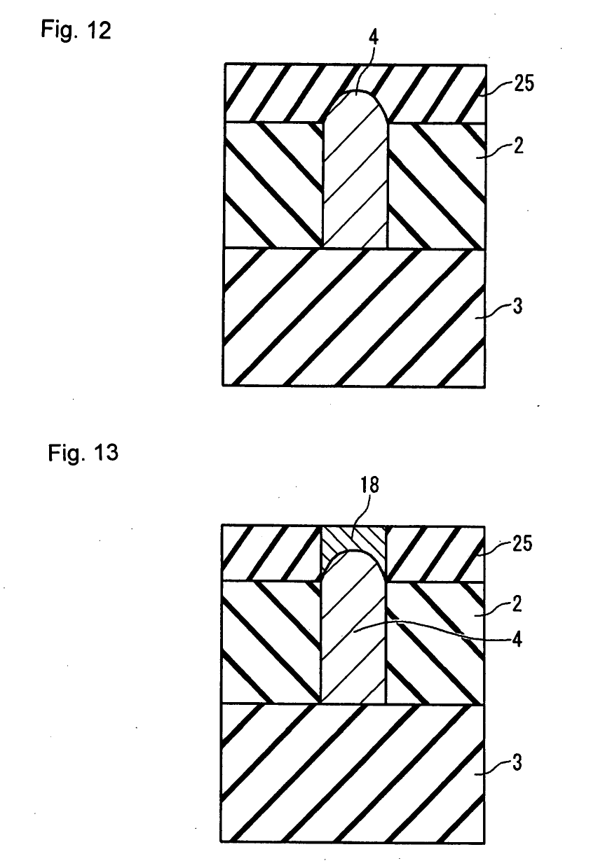

First, see FIGS. 10A, B. After forming the contact plug 4, part of the silicon oxide film 2 surrounding the contact plug 4 is removed by overall etching back using a fluorine-containing plasma. By this etching back, the shape of the polysilicon plug 4 becomes a convex shape protruding above from the surface of the silicon oxide film 2.

### Step S4, 5: Dopant Implantation and Hydrogen (H₂) Annealing

Next, see FIGS. 11A, B. As described in Embodiment 1, dopant implantation (S4) and hydrogen annealing (S5) are conducted. In this embodiment, since the polysilicon plug 4 protrudes as a convex, the shape of the upper surface of the polysilicon plug 4 after hydrogen annealing (S5) becomes a larger curvature than Embodiment 1.

### Step S6: Deposition of a Silicon Oxide Film

Next, see FIG. 12. A silicon oxide film 25 is deposited on the polysilicon plug 4 and the silicon oxide film 2 as an interlayer insulating film. The silicon oxide film 25 is formed by plasma CVD using TEOS as a starting material.

### Step S7, 11: Formation of a Contact Hole and Deposition of Polysilicon

Next, see FIG. 13. The silicon oxide film 25 is opened by lithography and a fluorine-containing plasma, to form a contact hole for connection to the upper surface of the polysilicon plug 4 (S7). Polysilicon is deposited over the whole surface and is then etched back, to form a polysilicon plug 18 (S11).

The above operations in Steps S1 to S11 forms a polysilicon plug comprising a structure comprising another polysilicon plug 18 on the polysilicon plug 4. In this embodiment, since the polysilicon plug 4 protrudes as a convex during hydrogen annealing (S5), the upper surface of the polysilicon plug 4 can be smooth with a larger curvature. Since a larger curvature of the interface between the polysilicon plug 4 and the polysilicon plug 18 leads to a larger contact area, a contact resistance can be reduced.

A curvature of the upper surface of the polysilicon plug 4 after hydrogen annealing can be adjusted by a height of the polysilicon plug 4 protruding from the silicon oxide film 2 before hydrogen annealing. Specifically, in the processing in Step S3-4, the etching-back amount of the silicon oxide film 2 can be adjusted to control a height of the convex in the polysilicon plug 4, whereby a desired curvature of the upper surface of the polysilicon plug 4 after hydrogen annealing can be obtained.

Although a polysilicon plug comprising the additional polysilicon plug 18 on the polysilicon plug 4 is formed in this embodiment, a tungsten plug may be deposited on the polysilicon plug 4 as described in Embodiment 1. Alternatively, in Embodiment 1, another polysilicon plug 18 may be deposited on the polysilicon plug 4 as described in this embodiment.

### Embodiment 3

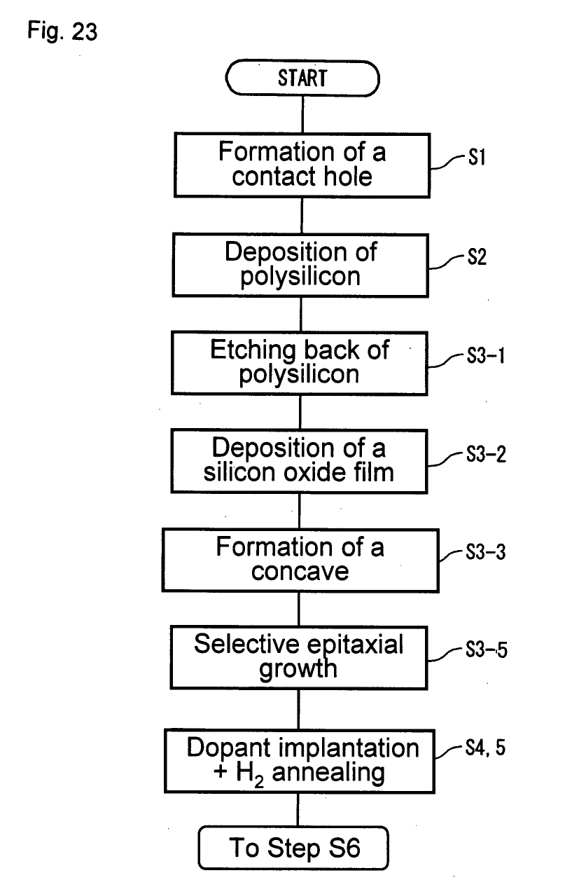

There will be described Embodiment 3. FIG. 23 is a flow chart of a manufacturing process for a semiconductor device according to this embodiment. In this embodiment, processing is conducted such that the upper surface of the polysilicon plug 4 is within a contact hole and has a concave shape. In comparison with Embodiments 1 and 2, it is modified in that silicon is selectively epitaxially grown. Each step will be described.

### Step S1, 2: Formation of a Contact Hole and Deposition of Polysilicon

As described in Embodiment 1, a contact hole 1 is formed (S1) and a polysilicon 4a is deposited (S2).

### Steps S3-1 to 3-5: Processing of Polysilicon into a Concave Shape and Selective Epitaxial Growth

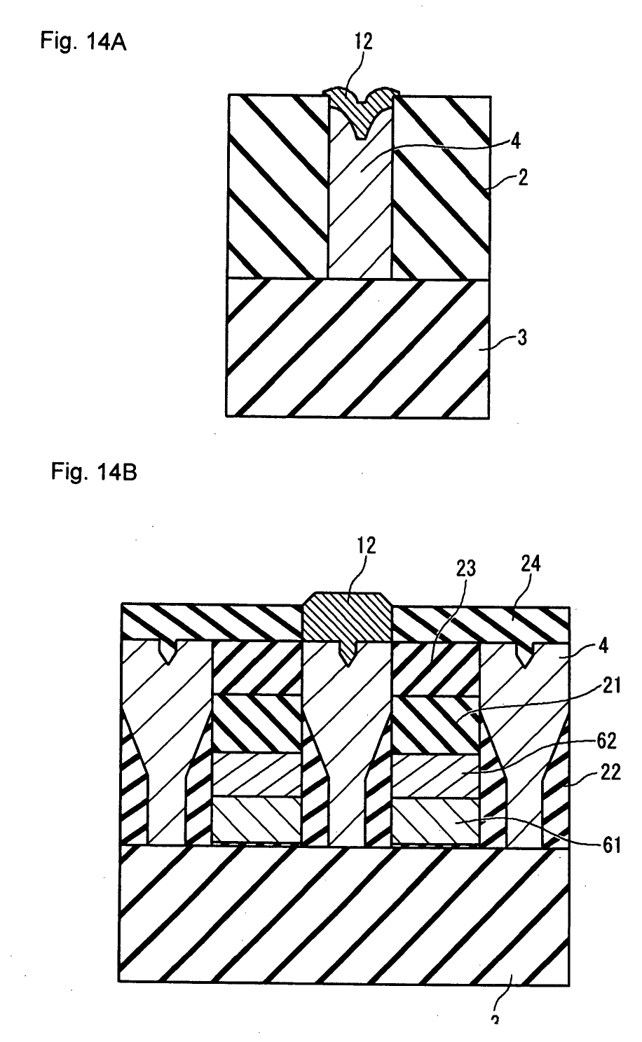

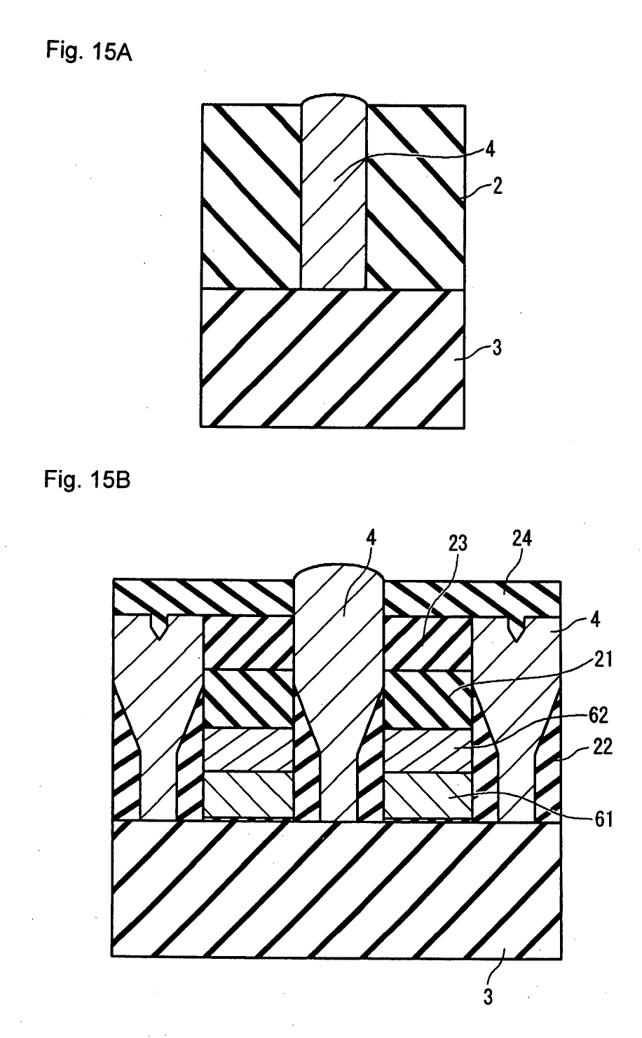

See FIGS. 14A, B. As described in Embodiment 1, the polysilicon 4a is etched back to form a polysilicon plug 4 (S3-1). Then, a silicon oxide film 24 to be an interlayer insulating film is deposited by plasma CVD using TEOS as a starting material (S3-2). Next, a hole is formed in the silicon oxide film 24 over the polysilicon plug 4 by dry etching using lithography and a fluorine-containing plasma. Thus, the upper surface of the polysilicon plug 4 is placed within the hole and has a concave shape (S3-3). The polysilicon 4a can be etched back to the inside of the contact hole 1 to form the concave as shown in FIG. 14A.

Then, silicon is selectively epitaxially grown on the upper surface of the polysilicon plug 4 (S3-5). In this selective epitaxial growth, a selective epitaxial silicon 12 is formed such that it fills the upper openings in the silicon oxide films 2 and 24. The selective epitaxial silicon 12 can be grown using dichlorosilane (SiH₂Cl₂) and hydrogen chloride (HCl) as a source gas at a temperature of 800° C. under a hydrogen atmosphere below an atmospheric pressure. Here, since hydrogen chloride inhibits formation of silicon nuclei on the silicon oxide film surface, silicon can be selectively grown only on the polysilicon plug surface.

### Step S4, 5: Dopant Implantation and Hydrogen Annealing

Next, see FIGS. 15A, B. After forming the selective epitaxial silicon 12, dopant implantation (S4) and hydrogen annealing (S5) are conducted as described in Embodiment 1. By the hydrogen annealing, silicon atoms move in the surface of the selective epitaxial silicon 12 such that local irregularity in the surface is evened. Consequently, a slightly convex and smooth surface can be obtained. In this embodiment, the polysilicon plug 4 is removed to the inside of the contact hole to form a concave, which is then filled with silicon by selective epitaxial growth. Therefore, movement of silicon atoms by hydrogen annealing can be more effective. Selective epitaxial growth may be applied to Embodiment 1.

### Embodiment 4

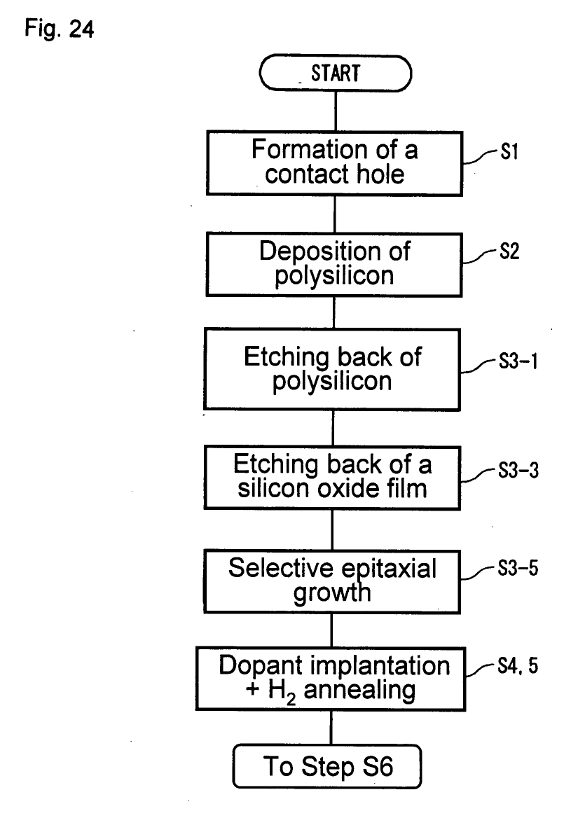

There will be described Embodiment 4. FIG. 24 is a flow chart of a manufacturing process for a semiconductor device according to this embodiment. This embodiment comprises the step of selective epitaxial growth of silicon as described in Embodiment 3. The shape of a polysilicon plug during the selective epitaxial growth of silicon in this embodiment is different from that in Embodiment 3. Each step will be described in detail.

### Step S1, 2: Formation of a Contact Hole and Deposition of Polysilicon

As described in Embodiment 1, a contact hole 1 is formed (S1) and polysilicon 4a is deposited (S2).

### Step S3-1; Etching Back of Polysilicon

Then the polysilicon 4a is etched back until the polysilicon 4a is buried to the substantially same level as the opening in the upper part of the contact hole 1, to form a polysilicon plug 4 (FIGS. 3A, B).

### Step S3-4; Etching Back of a Silicon Oxide Film

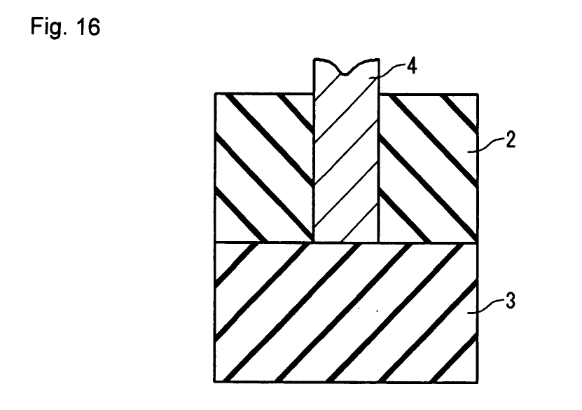

Next, see FIG. 16. After forming the polysilicon plug 4, a silicon oxide film 2 surrounding the polysilicon plug 4 is overall etched back by dry etching using a fluorine-containing plasma. Thus, the shape of the polysilicon plug 4 becomes a convex shape protruding from the surface of the silicon oxide film 2.

### Step S3-4: Selective Epitaxial Growth

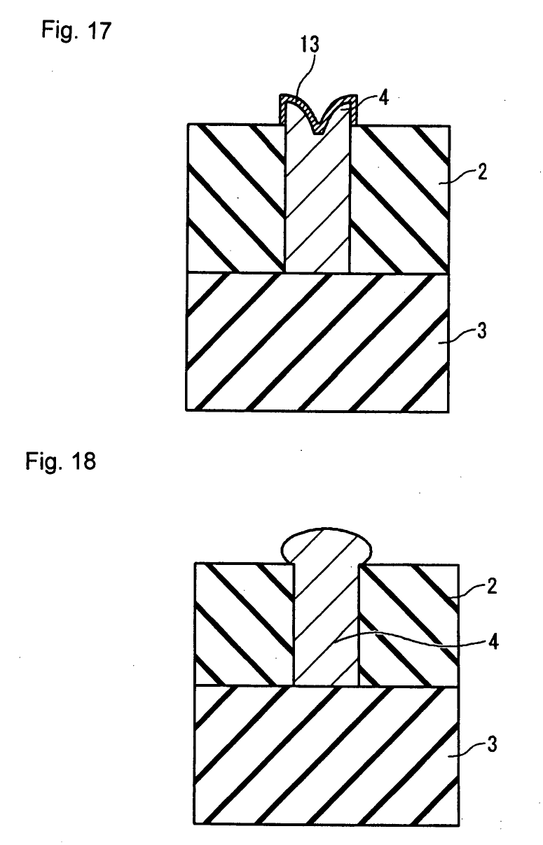

Next, see FIG. 17. As described in Embodiment 3, a selective epitaxial silicon 13 is grown over the upper surface of the polysilicon plug 4 by selective epitaxial growth. Here, since the polysilicon plug 4 protrudes from the silicon oxide film 2, the selective epitaxial silicon 13 grows not only on the upper surface but also on the side surface of the polysilicon plug 4.

### Steps S4, 5: Dopant Implantation and Hydrogen Baking

Next, see FIG. 18. In this step, as described in Embodiment 3, a dopant is implanted (S4) and hydrogen annealing is conducted (S5). By the hydrogen annealing, polysilicon protrudes from the hole in a transverse direction (a direction parallel to the substrate plane) in the upper part of the contact hole 1. The subsequent steps are as described in Embodiment 1 and thus omitted.

According to this embodiment, as described in Embodiment 3, since the amount of silicon which is fluidized during hydrogen annealing can be increased, the upper surface of the polysilicon can be more reliably made smooth. In addition, since the polysilicon plug 4 can protrude over the contact hole 1 in a transverse direction, a surface area of the upper surface of the polysilicon plug 4 can be further increased. This structure can further reduce a contact resistance with a contact structure connected to the upper surface of the polysilicon plug 4.

Thus, Embodiments 1 to 4 have been described. These embodiments can be used in combination as long as there are no contradictions.

A polysilicon plug formed by utilizing the concept of the present invention can be suitably used as a plug for interlayer connection in a DRAM comprising a layout with a narrow pitch like, for example, 6F2. Since the plan layout as shown in FIG. 19 has a narrow contact pitch and the plan layout requires reduction in a contact resistance of the plug, the use of the concept of the present invention is particularly advantageous.

1. A process for manufacturing a semiconductor device comprising the steps of:
forming a hole within an insulating layer on a semiconductor substrate;
forming a polysilicon over the whole surface of the insulating layer such that the polysilicon fills the hole;
forming a polysilicon plug in the hole by etching back the polysilicon; and
conducting hydrogen annealing by heating the semiconductor substrate comprising the polysilicon plug within the insulating layer under a hydrogen atmosphere.

2. The process for manufacturing a semiconductor device as claimed in claim 1, wherein the step of forming the polysilicon plug is the step of forming the polysilicon plug by etching back the polysilicon until the height of the opening in the hole become equal to that of the upper surface of the polysilicon plug.

3. The process for manufacturing a semiconductor device as claimed in claim 1, wherein the step of forming the polysilicon plug is the step of forming the polysilicon plug by etching back the insulating layer such that the upper part of the polysilicon plug has a convex shape protruding upward from the surface of the insulating layer.

4. The process for manufacturing a semiconductor device as claimed in claim 1, further comprising the step of selective epitaxial growth in which silicon is selectively epitaxially grown on a region where the polysilicon plug is exposed between the steps of forming the polysilicon plug and of conducting hydrogen annealing.

5. The process for manufacturing a semiconductor device as claimed in claim 1, wherein the polysilicon plug is formed as a plug connecting a bit line in a DRAM to an impurity diffusion layer, or a plug connecting a capacitor to an impurity diffusion layer.

6. The process for manufacturing a semiconductor device as claimed in claim 1, wherein the step of conducting hydrogen annealing is conducted under the conditions of a temperature of the semiconductor substrate comprising the polysilicon plug of 800° C. to 900° C. both inclusive and a duration of 10 sec to 60 sec both inclusive.

7. A semiconductor device comprising
a semiconductor substrate;
an insulating layer formed on the semiconductor substrate;
a hole formed within the insulating layer; and
a polysilicon plug buried in the hole,
wherein the upper surface of the polysilicon plug is a curved surface.

8. The process for manufacturing a semiconductor device as claimed in claim 2, further comprising the step of selective epitaxial growth in which silicon is selectively epitaxially grown on a region where the polysilicon plug is exposed between the steps of forming the polysilicon plug and of conducting hydrogen annealing.

9. The process for manufacturing a semiconductor device as claimed in claim 2, wherein the polysilicon plug is formed as a plug connecting a bit line in a DRAM to an impurity diffusion layer, or a plug connecting a capacitor to an impurity diffusion layer.

10. The process for manufacturing a semiconductor device as claimed in claim 2, wherein the step of conducting hydrogen annealing is conducted under the conditions of a temperature of the semiconductor substrate comprising the polysilicon plug of 800° C. to 900° C. both inclusive and a duration of 10 sec to 60 sec both inclusive.

11. The process for manufacturing a semiconductor device as claimed in claim 3, further comprising the step of selective epitaxial growth in which silicon is selectively epitaxially grown on a region where the polysilicon plug is exposed between the steps of forming the polysilicon plug and of conducting hydrogen annealing.

12. The process for manufacturing a semiconductor device as claimed in claim 3, wherein the polysilicon plug is formed as a plug connecting a bit line in a DRAM to an impurity diffusion layer, or a plug connecting a capacitor to an impurity diffusion layer.

13. The process for manufacturing a semiconductor device as claimed in claim 3, wherein the step of conducting hydrogen annealing is conducted under the conditions of a temperature of the semiconductor substrate comprising the polysilicon plug of 800° C. to 900° C. both inclusive and a duration of 10 sec to 60 sec both inclusive.
